(19) United States
(12) Patent Application Publication
(10) Pub. No.: US 2020/0263299 A1
(43) Pub. Date: Aug. 20, 2020

(54) SURFACE TREATMENT APPARATUS FOR SURFACE-TREATING POWDER AND METHOD OF SURFACE-TREATING POWDER USING THE SAME

(71) Applicants: Hyundai Motor Company, Seoul (KR); Kia Motors Corporation, Seoul (KR)

(72) Inventors: Woong Pyo Hong, Hwaseong (KR); Seung Jeong Oh, Hwaseong (KR); Jung Yeon Park, Hwaseong (KR); Jin Hyeok Cha, Hwaseong (KR); Hyung Sang Park, Seoul (KR); Chae Woong Kim, Daejeon (KR); Tae Ho Yoon, Anseong (KR); Kun Woo Park, Sejong (KR)

(21) Appl. No.: 16/431,676

(22) Filed: Jun. 4, 2019

(30) Foreign Application Priority Data
Feb. 19, 2019 (KR) 10-2019-0018910

(51) Int. Cl. C23C 16/455; C23C 16/06; C23C 16/44

(52) U.S. Cl. CPC C23C 16/45544; C23C 16/4417; C23C 16/45555; C23C 16/06

(57) ABSTRACT

A surface treatment apparatus includes a chamber defining an accommodation space therein, an injection part provided at a first end of the chamber so as to inject gas into the accommodation space, a discharge part provided at a second end of the chamber that is opposite the first end so as to discharge unreacted gas from the accommodation space, and at least one subchamber loaded in the accommodation space in the chamber between the first end and the second end, where powder is charged in the subchamber, and the subchamber includes a mesh structure provided in at least one surface of the subchamber so as to allow the gas to be introduced into the subchamber, and the subchamber is movable from the first end to the second end.

### CROSS-REFERENCE TO RELATED APPLICATION

This application claims under 35 U.S.C. § 119(a) the benefit of Korean Patent Application No. 10-2019-0018910 filed on Feb. 19, 2019, the entire contents of which are incorporated herein by reference.

### BACKGROUND

### (a) Technical Field

The present disclosure relates to a surface treatment apparatus for surface-treating powder and a method of surface-treating powder using the same.

### (b) Description of the Related Art

In order to coat the surface of powder with a specific material, an atomic layer deposition (ALD) process or the like may be used. Referring to FIG. 1 (RELATED ART), a conventional surface treatment apparatus for surface-treating powder, which is used to perform an atomic-layer-deposition (hereinafter, referred to as “ALD”) process, is illustrated. In particular, the process may be performed in such a manner as to introduce the material to be coated (particularly, powder) into a gas deposition chamber (or a reaction chamber) and then introduce a metal precursor gas or the like into the reaction chamber. Consequently, since the surfaces of particles of the material to be coated are exposed to the metal precursor gas, the metal precursor gas may be deposited on the surfaces of the particles. In addition, a process of removing air, water vapor, contaminants and the like, which are unnecessary for the deposition, from the reaction chamber may also be performed in conjunction with the ALD process.

Further, the ALD technology may be used to produce a metal/carbon catalyst for fuel cells (for example, a platinum/carbon (Pt/C) catalyst). In particular, the ALD process may be performed in a dry-type manner or in a wet-type manner. The dry-type ALD process is able to reduce the production time of the catalyst. In addition, since the dry-type ALD process does not discharge waste water unlike the wet-type ALD process, it is a more eco-friendly process.

However, such a conventional ALD process has disadvantages in that mass production is difficult and it is impossible to uniformly deposit a metal precursor on the surfaces of particles of material to be coated. Accordingly, it would be desirable to provide a surface treatment apparatus for surface-treating powder and a method of surface-treating powder using the same, which are able to deposit a metal catalyst on powder (i.e., a support) by maximizing surface area thereof even though the expensive metal catalyst is used in a small amount.

### SUMMARY

The present disclosure provides a surface treatment apparatus for surface-treating powder and a method of surface-treating powder using the same, which are able to uniformly coat the surface of powder with a metal precursor and to reduce the consumption of the metal precursor attributable to continuous flow of the metal precursor.

It is another object of the present disclosure to produce powder that is uniformly supported by the metal precursor by uniformly depositing the metal precursor on the surface of the powder in atomic-layer units even when the size of the chamber of the surface treatment apparatus is increased.

It is yet another object of the present disclosure to prevent powder, which has a nano size (nm) or micro size (μm) and floats in a reaction chamber, from being lost owing to pumping and discharge of unreacted gas.

Objects of the present disclosure are not limited to the above-mentioned objects. Other specific details of the present disclosure will be apparent from the following detailed description and the accompanying drawings.

In one aspect, the present disclosure provides a surface treatment apparatus for surface-treating powder including a chamber defining an accommodation space therein, an injection part provided at a first end of the chamber so as to inject gas into the accommodation space, a discharge part provided at a second end of the chamber that is opposite the first end so as to discharge unreacted gas from the accommodation space, and at least one subchamber loaded into the accommodation space in the chamber between the first end and the second end, wherein powder is charged in the subchamber, wherein the subchamber includes a mesh structure provided in at least one surface of the subchamber so as to allow the gas to be introduced into the subchamber, and wherein the subchamber is movable from the first end to the second end.

In a preferred embodiment, the gas may be injected into the accommodation space from the injection part at least once when the subchamber is moved toward the second end from the first end.

In another preferred embodiment, the gas may contact the powder charged in the subchamber so as to perform atomic layer deposition (ALD).

In still another preferred embodiment, the mesh structure may include a micro-hole, and a size of the micro-hole may be larger than a size of a particle included in the gas but smaller than the powder.

In yet another preferred embodiment, the size of the micro-hole may be in a range of 10 μm to 100 μm.

In still yet another preferred embodiment, the surface treatment apparatus may further include a controller, the controller being able to load the subchamber in the accommodation space toward the first end, and to remove the subchamber from the accommodation space after the subchamber has been moved toward the second end.

In a further preferred embodiment, the surface treatment apparatus may further include a pumping part, the pumping part discharging the unreacted gas in the accommodation space to an outside of the accommodation space through the discharge part.

In another further preferred embodiment, when a first subchamber in the chamber is moved toward the second end, a second subchamber may be added to the chamber at approximately the first end so as to be moved toward the second end.

In still another further preferred embodiment, the accommodation space in the chamber between the first end and the second end may be compartmented into N sections (N being a natural number equal to or greater than 2), and the subchamber may be moved from a first section at approximately the first end to an Nth section at approximately the second end in a stepwise fashion.

In yet another further preferred embodiment, when a first subchamber is moved from a first section toward an Nth section, a second subchamber may be added to the first section so as to be moved toward the Nth section.

In still yet another further preferred embodiment, when the subchamber is moved to a next section and is positioned thereat, gas may be injected into the accommodation space from the injection part.

In a still further preferred embodiment, the surface treatment apparatus may further include a controller, the controller being able to load the subchamber into the first section in the accommodation space, and to remove the subchamber from the accommodation space when the subchamber is positioned at the Nth section.

In a yet still further preferred embodiment, the powder may include carbon (C), and the gas may include a metal precursor.

In another aspect, the present disclosure provides a method of surface-treating powder using the surface treatment apparatus including loading a first subchamber in the accommodation space so as to be closer to the first end than the second end, moving the first subchamber toward the second end, and loading a second subchamber into the accommodation space between the first subchamber and the first end, wherein when the first subchamber is moved, gas is injected into the accommodation space from the injection part at least once.

In a preferred embodiment, the accommodation space between the first end and the second end may be compartmented into N sections (N being a natural number equal to or greater than 2), loading the first subchamber into the accommodation space may include loading the first subchamber into a first section at approximately the first end, moving the first subchamber toward the second end may include moving the first subchamber from the first section to an Nth section at approximately the second end in a stepwise fashion, and loading the second subchamber into the accommodation space may include additionally loading the second subchamber into the first section when the first subchamber is moved toward the Nth section.

In another preferred embodiment, as the first subchamber is moved from the first section toward the Nth section in a stepwise fashion, the second subchamber, which has been added to the first section, may be also moved toward the Nth section.

In still another preferred embodiment, when the subchamber is moved from a section to another adjacent section and is positioned thereat, gas may be injected into the accommodation space from the injection part at least once.

In yet another preferred embodiment, when the subchamber is positioned at the Nth section in the accommodation space, the subchamber may be removed under a control of a controller.

In still yet another preferred embodiment, injecting the gas may include a first operation of supplying the gas including a metal precursor, a second operation of performing purging with inert gas, a third operation of supplying reaction gas for converting the metal precursor into metal, and a fourth operation of performing purging with inert gas.

In a further preferred embodiment, the first to fourth operations may be set to be one cycle, and the operations may be performed for one or more cycles.

Other aspects and preferred embodiments of the disclosure are discussed infra.

The above and other features of the disclosure are discussed infra.

### BRIEF DESCRIPTION OF THE DRAWINGS

The above and other features of the present disclosure will now be described in detail with reference to certain exemplary embodiments thereof illustrated in the accompanying drawings which are given hereinbelow by way of illustration only, and thus are not limitative of the present disclosure, and wherein:

FIG. 1 (RELATED ART) is a cross-sectional view illustrating a conventional surface treatment apparatus for surface-treating powder;

FIG. 2 is a cross-sectional view illustrating a surface treatment apparatus for surface-treating powder according to some embodiments of the present disclosure;

FIG. 3 is a cross-sectional view illustrating a subchamber according to an embodiment of the present disclosure;

FIGS. 4 to 6 are views illustrating a surface treatment apparatus for surface-treating powder according to some embodiments of the present disclosure;

FIGS. 7 and 8 are cross-sectional views illustrating subchambers according to other embodiments of the present disclosure;

FIGS. 9 and 10 are flowcharts illustrating methods of surface-treating powder according to some embodiments of the present disclosure;

FIG. 11 is a flowchart illustrating an operation of a controller; and

FIGS. 12 to 14 are images of scanning transmission electron microscopy (STEM) illustrating the results of experimental examples of the present disclosure.

It should be understood that the appended drawings are not necessarily to scale, presenting a somewhat simplified representation of various preferred features illustrative of the basic principles of the disclosure. The specific design features of the present disclosure as disclosed herein, including, for example, specific dimensions, orientations, locations, and shapes will be determined in part by the particular intended application and use environment.

In the figures, the reference numbers refer to the same or equivalent parts of the present disclosure throughout the several figures of the drawing.

### DETAILED DESCRIPTION

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Hereinafter reference will be made in detail to various embodiments of the present disclosure, examples of which are illustrated in the accompanying drawings and described below. While the disclosure will be described in conjunction with exemplary embodiments, it will be understood that the present description is not intended to limit the disclosure to the exemplary embodiments. On the contrary, the disclosure is intended to cover not only the exemplary embodiments, but also various alternatives, modifications, equivalents and other embodiments within the spirit and scope of the disclosure as defined by the appended claims. In the following description of the embodiments, the same elements are denoted by the same reference numerals even though they are depicted in different drawings.

Hereinafter, the present disclosure will be described in detail with reference to the accompanying drawings.

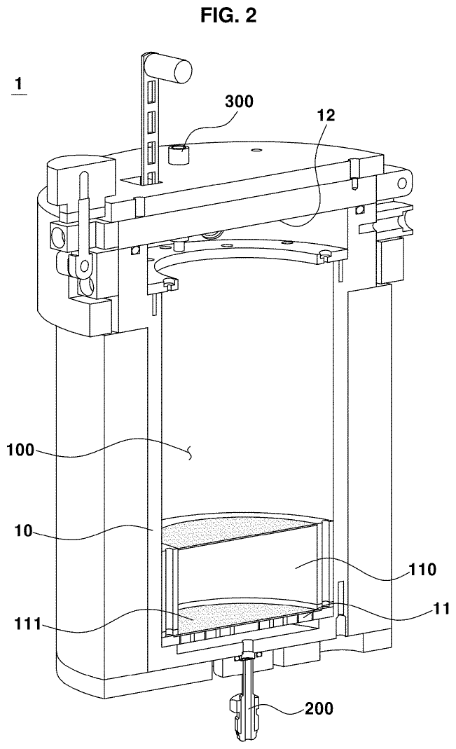

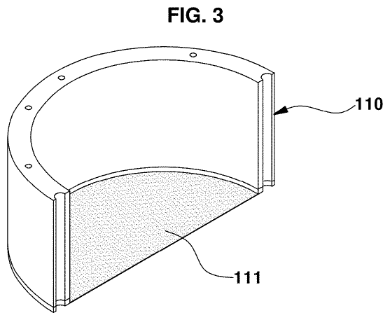

FIGS. 2 and 3 are cross-sectional views illustrating a surface treatment apparatus and a subchamber according to some embodiments of the present disclosure.

Referring first to FIG. 2, the surface treatment apparatus 1 for surface-treating powder may include a chamber 10 defining therein an accommodation space 100, an injection part 200 provided at a first end 11 of the chamber 10 so as to inject gas into the accommodation space 100, and a discharge part 300 provided at a second end 12 of the chamber 10, which is opposite the first end 11, so as to discharge unreacted gas from the accommodation space 100.

In this embodiment, at least one subchamber 110 may be loaded in the accommodation space 100 defined in the chamber 10 so as to be disposed between the first end 11 and the second end 12. The subchamber 110 may be filled with powder, which is to be surface-treated. As illustrated in FIG. 2, the subchamber 110 may be loaded in the accommodation space 100 near the first end 11 and may be moved toward the second end 12 from the first end 11. Accordingly, as the subchamber 110 moves closer to the second end 12 than the first end 11, the subchamber 110 may become distant from the injection part 200. Consequently, the contact area between the gas supplied from the injection part 200 and the powder in the subchamber 110 may be decreased.

Although FIG. 2 illustrates a structure in which a groove is formed in a portion of the chamber 10 and a portion of the subchamber 110 is engaged with the groove such that the subchamber 110 is loaded and moved, the present disclosure is not limited thereto, and the subchamber 110 may be loaded into the accommodation space 100 in various manners.

In the chamber 10 of the surface treatment apparatus 1 for surface-treating powder according to an embodiment of the present disclosure, when a first subchamber 110 moves toward the second end 12, a second subchamber, which is additionally provided at approximately (i.e., located close to) the first end 11, may also move toward the second end 12. In other words, one or more subchambers may move together toward the second end 12 from the first end 11, thereby implementing a continuous process. As used herein, the terms “approximately,” “close to,” etc. denote a location in the chamber 10 that is in a vicinity of or adjacent to the first end 11 or the second end 12, for example.

Although not illustrated in FIG. 2, the surface treatment apparatus 1 for surface-treating powder according to some embodiments of the present disclosure may further include a controller. For example, the controller may load the subchamber 110 into the accommodation space 100 so as to be closer to the first end 11 than the second end 12. Further, the controller may remove (i.e. unload) the subchamber 110 from the accommodation space 100 after the subchamber 110 has moved toward the second end 12.

Although not illustrated in FIG. 2, the surface treatment apparatus for surface-treating powder according to some embodiments of the present disclosure may further include a pumping part. The pumping part may move unreacted gas in the accommodation space 100 (for example, remaining gas left after contact between the powder and the gas in the subchamber 110) to the discharge part 300 so as to discharge the unreacted gas to the outside.

The powder, which is loaded in the subchamber 110 and is to be surface-treated, may include, for example, carbon C. Although the powder may include carbon black, the present disclosure is not limited thereto. The gas supplied from the injection part 200 may include a metal precursor. Preferably, the metal precursor may include a Pt precursor. The Pt precursor may be stored in, for example, a canister. In this case, although the Pt precursor may be injected into the accommodation space 100 in the chamber 10 by opening an injection port of the canister, the present disclosure is not limited thereto. After the metal precursor is deposited on the powder, the metal precursor may be converted into a metal.

Prior to filling the subchamber 110 with powder, an operation of acid-treating the powder or screening the powder into a predetermined size range (for example, grain size of 200 μm to 500 μm) may be performed. Consequently, contact between the powder and the gas may be more efficiently realized, and it is possible to prevent the loss of powder from the subchamber 110.

Although the internal pressure in the chamber 10 may be maintained in a vacuum state of 1 torr, the present disclosure is not limited thereto. Further, although the internal temperature in the chamber 10 may be maintained, preferably at a temperature of 200° C. to 250° C. for 1 hour or more, the present disclosure is not limited thereto.

The structure of the subchamber 110 is particularly illustrated in FIG. 3.

As illustrated in FIG. 3, at least one surface of the subchamber 110 may be provided with a mesh structure 111. The mesh structure 111 may include micro-holes. Consequently, the gas, which is supplied into the accommodation space 100 (see FIG. 2) from the injection part 200 (see FIG. 2), may move into the subchamber 110 through the mesh structure 111. Unreacted gas may move to the discharge part 300 (see FIG. 2) and then be discharged to the outside.

Each of the micro-holes may be larger than the particles included in the gas supplied from the injection part 200 but may be smaller than the powder loaded into the subchamber 110. As a result, upon pumping and discharge of unreacted gas, it is possible to prevent loss of powder, which is caused by powder having a nano size (for example, 30-50 nm) or a micro size (for example, 200-500 μm) floating in the accommodation space 100.

When a plurality of subchambers are loaded into the accommodation space 100, micro-holes in the subchambers may have the same size.

In particular, the size of the micro-holes may be, for example, in a range of 10 μm to 100 μm. Since the size of the micro-holes is equal to or larger than 10 μm, gas may move therethrough, and thus there is no influence on the pumping performance. When the powder loaded in the subchamber is, for example, carbon black, the powder cannot pass through the micro-holes and thus cannot move outside the subchamber 110 because the size of the carbon black is in a range of 200 μm to 500 μm. Even when the size of the powder that is initially loaded in the subchamber, is in a range of 30 nm to 50 nm, the powder may agglomerate together by virtue of contact between the powder, and may thus have various sizes (i.e., 200 μm to 500 μm). Hence, the powder may not pass through the micro-holes and may not move outside the subchamber 110.

When a metal precursor (for example, a Pt precursor) is included in the gas, it is possible to prevent powder with the metal precursor supported thereon, which is generated by contact between the powder and the gas, from moving from one subchamber 110 into another subchamber.

The mesh structure 111 may be configured to face, for example, the injection part 200 and the discharge part 300. Consequently, the gas supplied from the injection part 200 may move to the discharge part 300 through the subchamber 110. Although the mesh structure 111 is illustrated as being provided at a single surface of the subchamber 110 in FIG. 3, the present disclosure is not limited thereto. In other words, various numbers of mesh structures 111 may be provided at various positions of the subchamber 110. For example, the mesh structure 111 may be provided at opposite surfaces of the subchamber 110.

Referring again to FIG. 2, in the surface treatment apparatus for surface-treating powder according to the present disclosure, the gas may be injected into the accommodating space 100 from the injection part 200 one or more times while the subchamber 110 (see FIG. 3) moves to the second end 12 from the first end 11. Accordingly, when the subchamber 110 is loaded in the accommodation space 100, the gas may be injected into the subchamber 110 through the mesh structure 111 of the subchamber 110. Consequently, the powder loaded in the subchamber 110 may come into contact with the gas. In other words, the powder may be subjected to atomic layer deposition (ALD) by virtue of injection of gas into the subchamber 110.

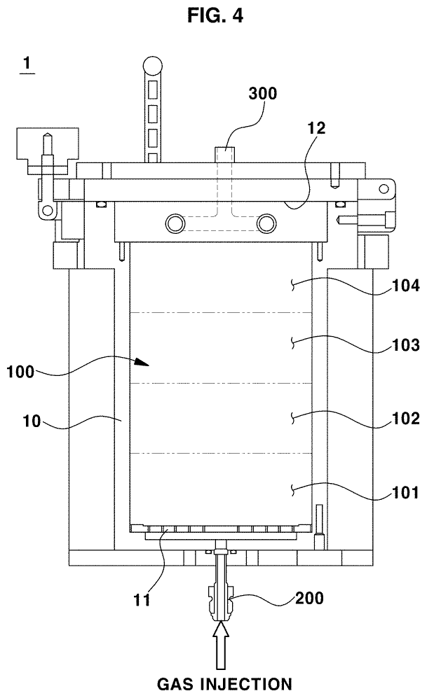

FIGS. 4 to 6 are views illustrating the surface treatment apparatus for surface-treating powder according to some embodiments of the present disclosure.

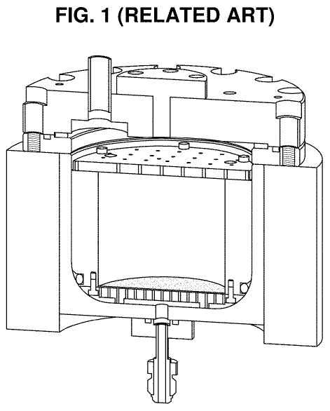

For the convenience of explanation, a description will be mainly given of parts that are different from the parts that have been described with reference to FIGS. 1 to 3.

First, the surface treatment apparatus 1 for surface-treating powder in which the subchamber (see FIG. 3) is not loaded in the accommodation space 100 will be described with reference to FIG. 4.

Referring to FIG. 4, the accommodation space 100 in the chamber 10 between the first end 11 and the second end 12 may be compartmented into four sections 101, 102, 103 and 104. Accordingly, the subchamber (see FIG. 3) may move in a stepwise fashion from the first section 101 near the first end 11 to the fourth section 104 near the second end 12. In particular, the subchamber 110 may move in a stepwise fashion from the first section 101 to the second section 102, from the second section 102 to the third section 103, and from the third section 103 to the fourth section 104.

Every time the subchamber is positioned at a next section (i.e., every time the subchamber moves from a section closer to the first end 11 to a next section in a direction toward the second end 12), the gas may be injected into the accommodation space 100 from the injection part 200 provided at the first end 11 of the chamber 10. Accordingly, as the subchamber moves toward the fourth section 104 from the first section 101, the amount of gas contacting the powder in the subchamber may be reduced.

As described above, the surface treatment apparatus 1 for surface-treating powder may further include the controller, and the controller may load the subchamber into the first section 101 of the accommodation space 100. Further, the controller may remove the subchamber from the accommodation space 100 when the subchamber is positioned in the fourth second 104 after passing through the previous sections.

When the first subchamber moves toward the fourth section 104 from the first section 101, the second subchamber may be additionally provided in the first section 101 and may move toward the fourth second. In particular, when the first subchamber moves to the second section 102 from the first section 101, the second subchamber may be additionally loaded in the first section 101. Consequently, the first and second subchambers may be positioned adjacent to each other and may move together toward the fourth section.

Although the accommodation space 100 is illustrated in FIG. 4 as being compartmented into the four sections, the present disclosure is not limited thereto. In other words, in the chamber 10 of the surface treatment apparatus 1 for surface-treating powder according to some embodiments of the present disclosure, the accommodation space 100 defined between the first end 11 and the second end 12 may be compartmented into N sections (N being a natural number equal to or greater than 2), and the subchamber may move in sequence to the Nth section at approximately (or close to) the second end 12 from the first section at approximately (or close to) the first end 11. Accordingly, when the first subchamber moves in a stepwise fashion toward the Nth section from the first section, the second subchamber may be additionally provided in the first section and may move toward the Nth section. The controller may remove the subchamber positioned in the Nth section from the accommodation space 100.

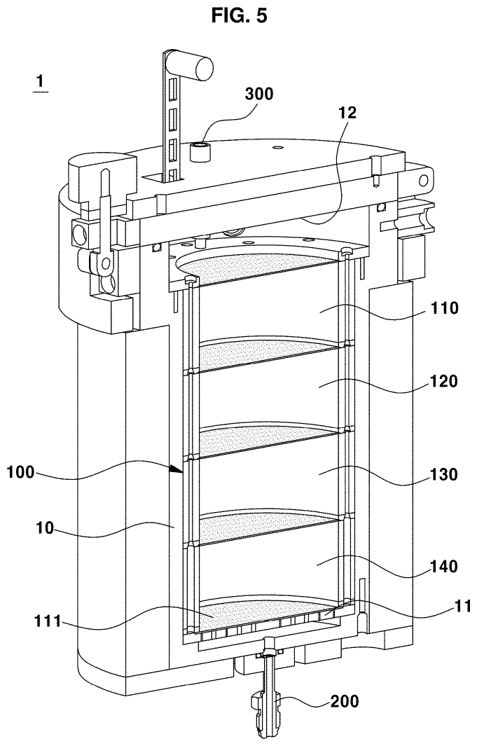

Next, the surface treatment apparatus 1, in which the subchambers are respectively loaded in all the four sections 101, 102, 103 and 104 (see FIG. 4) shown in FIG. 4 and which is in the process of injecting gas, will be described with reference to FIG. 5.

Referring to FIG. 5, the first subchamber 110, which has moved to the fourth section 104 at approximately (or close to) the second end 12 from the first section 101, is illustrated. The second to fourth subchambers 120, 130 and 140 are sequentially provided in the accommodation space 100. The subchambers 110, 120, 130 and 140 may move together to a section closer to the second end 12. Accordingly, when the first subchamber 110 is positioned in the fourth section 104 as illustrated in FIG. 5, the second to fourth subchambers 120, 130 and 140 may be sequentially positioned in the third to first sections 103, 102 and 101. Here, the first subchamber 110 may be removed from the fourth section 104. Because the first subchamber 110 is removed, the second subchamber 120 may move to the fourth section 104 from the third section 103.

The loading, unloading or movement of the subchambers 110 to 140 may be performed manually or automatically. For example, when the subchambers 110 to 140 are automatically loaded, unloaded or moved, the surface treatment apparatus 1 for surface-treating powder may further include an automatic control system.

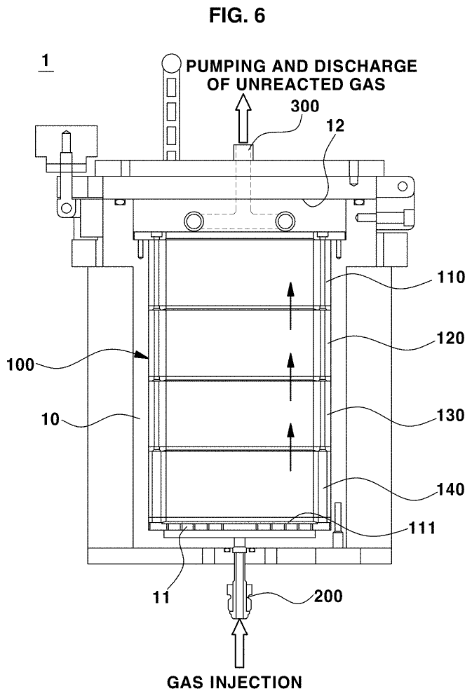

Referring to FIG. 6, gas may be injected into the accommodation space 100 in the chamber 10 from the injection part 200, and unreacted gas may be discharged to the outside of the chamber 10 through the discharge part 300. For example, every time each of the subchambers 110 to 140 moves to the next section (i.e., every time the subchamber moves to a section closer to the second end 12 from a section closer to the first end 11), gas may be injected into the accommodation space 100 from the injection part 200 provided at the first end 11 of the chamber 10. Accordingly, the amount of gas contacting powder in the first chamber 110, which is positioned closer to the second end 12 than to the first end 11, may be smaller than the amount of gas contacting powder in the fourth subchamber 140, which is positioned closer to the first end 11 than to the second end 12.

Particularly, because the second to fourth subchambers 120 to 140 are positioned between the first subchamber 110 and the injection part 200, gas is supplied in the sequence at approximately (or close to) the injection part 200 (i.e., in the sequence from the fourth subchamber 140 to the first subchamber 110). Accordingly, powder in a subchamber closer to the second end 12 (for example, the second subchamber 120) may contact remaining gas, which has passed through a subchamber closer to the first end 11 (for example, the third subchamber 130) and has reached the second subchamber 120. Consequently, the subchamber closer to the second end 12 may contact a smaller amount of gas than the subchamber closer to the first end 11.

In comparison with a process of filling the entire accommodation space 100 with powder and then repeatedly supplying gas from the injection part 200 (for example, supplying gas 20 times) without division of the chamber into the subchambers, a process of repeatedly supplying gas while sequentially moving a plurality of subchambers loaded in the accommodation space 100 toward the second end 12 (for example, sequentially moving the subchambers to the second end 12 from the first end 11 four times and supplying gas five times every time the subchambers move) may prevent overgrowth and may uniformly coat powder with the gas. In other words, it is possible to perform uniform surface treatment of powder even when supplying the same amount of gas the same number of times (or for the same duration).

The addition and removal of the subchambers may be performed, for example, automatically. After completion of the entire process, the surface-treated powder may be recovered from the surface treatment apparatus.

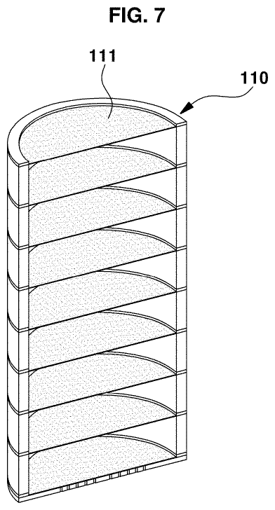

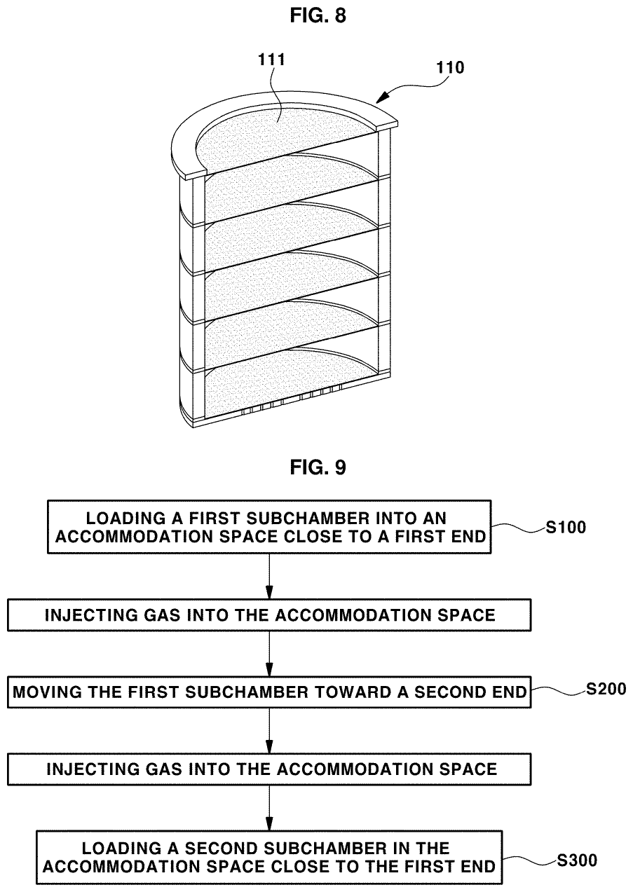

FIGS. 7 and 8 are cross-sectional views illustrating a subchamber according to another embodiment of the present disclosure. For the convenience of explanation, description will be mainly given of parts, which are different from the parts that have been described with reference to FIGS. 1 to 3.

Referring first to FIG. 7, eight subchambers 10 including mesh structures 111 may be disposed in the accommodation space 100 (see FIG. 6) of the chamber 10 (see FIG. 6). The surface area of the subchambers 110 may be, for example, twice the surface area of the subchamber shown in FIG. 3. Consequently, the amount of powder that can be loaded and surface-treated in all the subchambers 110 shown in FIG. 7, may be increased (for example, 50 g) compared to the amount of powder that can be loaded and surface-treated in the entire subchamber shown in FIG. 3 (for example, 3 g).

Referring to FIG. 8, the total number of subchambers 110 may be five, and the surface area of the subchambers 110 may be three times the surface area of the subchamber shown in FIG. 3. Consequently, the amount of powder that can be loaded and surface-treated in all the subchambers 110 shown in FIG. 8, may be increased (for example, 50 g) compared to the amount of powder that can be loaded and surface-treated in the entire subchamber shown in FIG. 3 (for example, 3 g). Accordingly, it is possible to maximize the effect of surface treatment of powder loaded in the subchambers by controlling the size or number of the subchambers 110 loaded in the accommodation space.

Hereinafter, a method of surface-treating powder using the surface treatment apparatus according to some embodiments of the present disclosure will be described with reference to FIGS. 9 to 11. For the convenience of explanation, a description will be provided of parts that are different from the parts that have been described with reference to FIGS. 1 to 8.

Referring first to FIG. 9, the method of surface-treating powder according to an embodiment of the present disclosure may include an operation (S100) of loading the first subchamber into the accommodation space so as to be closer to the first end than to the second end, an operation (S200) of moving the first subchamber toward the second end, and an operation (S300) of loading the second subchamber into the accommodation space between the first subchamber and the first end.

In this method of surface-treating powder, after the first subchamber is moved, gas may be injected into the accommodation space one or more times.

Here, the operation of injecting gas into the accommodation space may include a first operation of supplying gas including a metal precursor, a second operation of performing purging with inert gas, a third operation of supplying reaction gas for converting the metal precursor into a metal, and a fourth operation of performing purging with inert gas.

In the operation of injecting gas into the accommodation space, the process of sequentially performing the first to fourth operations may be set to be one cycle, and may be performed for one or more cycles.

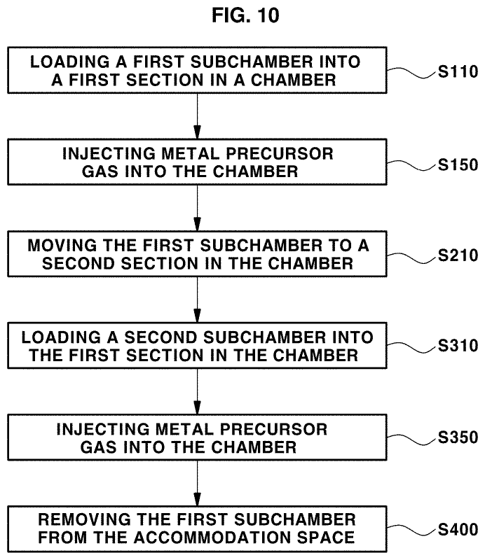

Referring next to FIG. 10, the accommodation space in the chamber between the first end and the second end may be compartmented into two sections. In this case, a method of surface-treating powder according to another embodiment of the present disclosure may include an operation (S110) of loading the first subchamber into the first section at approximately (or close to) the first end, an operation (S210) of moving the first subchamber from the first section to the second section, which is closer to the second end, and an operation (S310) of additionally loading the second subchamber into the first section after the movement of the first subchamber to the second section.

Every time each of the subchambers is moved from a section to another adjacent section, operation (S150 and S350) of injecting gas (including, for example, a metal precursor) into the accommodation space from the injection part may be performed.

Subsequently, an operation (S400) of removing the first subchamber from the accommodation space in the chamber by the controller after injecting gas into the accommodation space after movement of the first subchamber to the second section in the accommodation space may be performed.

Although the accommodation space is illustrated in FIG. 10 as being compartmented into two sections, the present disclosure is not limited thereto. In other words, the accommodation space defined between the first end and the second end may be compartmented into N sections (N being a natural number equal to or greater than 2). Here, the first subchamber may move closer to the second end in a stepwise fashion from the first section to the Nth section. Accordingly, the second subchamber may be additionally loaded into the first section and may move to the Nth section.

In addition to the first and second subchambers, another subchamber may be additionally loaded into the first section. In particular, as the subchamber, which has been previously loaded, moves in a stepwise fashion from the first section toward the Nth section, the subchamber, which has been additionally loaded, may also move toward the Nth section. As described above, every time each of the subchambers moves from a section to another adjacent section, gas may be injected into the accommodation space once with the aim of surface-treating powder.

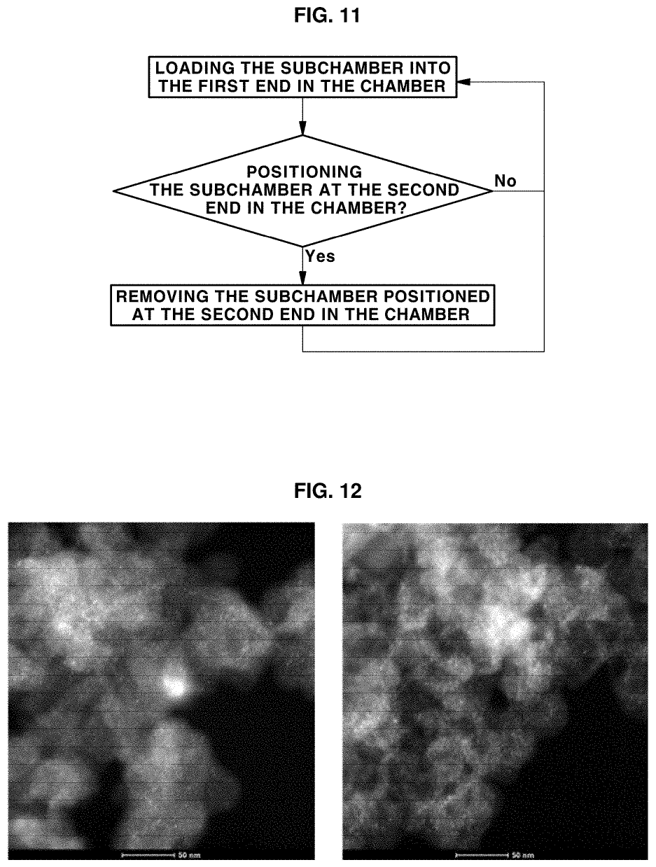

Referring next to FIG. 11, a flowchart of the operation (S400, see FIG. 10) of removing the first subchamber by the controller is illustrated.

The controller may determine whether a subchamber is positioned at the second end at approximately (or close to) the discharge part after the subchambers sequentially move from the first end toward the second end. The subchamber that is determined to be positioned at the second end may be removed from the chamber (i.e., the accommodation space). Accordingly, an additional subchamber may be loaded into the first section at approximately (or close to) the first end 11.

When the controller does not determine that a subchamber is positioned at the second end, a subchamber, which is already loaded in the chamber, may be moved to the second end so as to allow a new additional subchamber to be loaded. When a subchamber, which is already loaded in the chamber, is positioned at the second end by loading a new additional subchamber, the controller may perform control to remove the subchamber positioned at the second end from the chamber.

Hereinafter, the present disclosure will be described in detail with reference to examples and experimental examples. The following examples are for illustrative purposes, and the scope of the present disclosure is not limited to the examples.

### EXAMPLE

(1) Carbon black was screened to a size of 200 μM to 500 μm.

(2) The accommodation space in the chamber (a fluid bed reactor, FBR) was compartmented into first to fourth sections from the injection part toward the discharge part, and the carbon black of 3 g that had been screened in the operation (1) was loaded into the subchamber.

(3) The internal pressure in the chamber was maintained at 1 ton. The internal temperature in the chamber was maintained at 200° C. to 250° C. for 1 hour.

(4) A Pt precursor was introduced into the chamber by opening the inlet of the canister containing the Pt precursor therein.

(5) Injection of a Pt precursor, purging with inert gas and purging with reaction gas (Oxygen (O₂), Ozone (O₃) or the like) and inert gas, which are sequentially performed as an ALD process, was set to be one cycle, and the process was repeatedly performed a total of 5 cycles.

(6) The subchamber disposed in the first section was moved to the second section, and a new subchamber was loaded into the first section.

(7) The operations of (1) to (5) were repeated, and then the subchamber disposed in the second section was moved to the third section. Subsequently, the subchamber disposed in the first section was moved to the second section, and a new subchamber was loaded into the first section.

(8) The operations of (1) to (5) were repeated, and then the subchamber disposed in the third section was moved to the fourth section. Subsequently, the subchamber disposed in the second section was moved to the third section, and then the subchamber disposed in the first section was moved to the second section. Thereafter, a new subchamber was additionally loaded into the first section.

(9) The operations of (1) to (5) were repeated, and the subchamber disposed in the fourth section was removed, followed by completion of the process. The conditions and results of the process are shown in Table 1.

### Comparative Example

The operations of (1) to (5) in the above example were performed, with the exception that the carbon black that had been screened in operation (1) in the above example was loaded into the accommodation space in the chamber without compartmenting the accommodation space in the chamber into the subchambers. Here, the charging amount of powder was 1 g. The ALD process in the operation (5) was repeatedly performed 20 cycles rather than 5 cycles. Conditions and results of the process are shown in Table 1.

TABLE 1

| | | Charging | | | | |
|---|---|---|---|---|---|---|
| | | amount | | | | |
| | | of powder | | | | ECSA |
| | | [g] | cycle | QH[mC] | wt % | [m2/g] |
| Compara- | — | 1 | 20th | 16.239 | 26.80 | 111.8 |
| tive | | | | | | |
| Example | | | | | | |
| Example | Subchamber | 3 | 5th | 9.1 | 13.1 | 111.5 |
| | in first | | | | | |
| | subchamber | | | | | |
| | Subchamber | 3 | 20th | 17.1 | 14.3 | 189.6 |
| | in fourth | | | | | |
| | subchamber | | | | | |

### Experimental Example 1: Comparison of Charging Amount of Powder

It will be appreciated that a charging amount of powder in the Example is increased to 12 g from 1 g in the Comparative Example under the conditions of the same time (i.e., the same number of cycles). In particular, powder of 1 g is charged into one chamber in the Comparative Example. In contrast, in the Example, a plurality of subchambers each including 3 g of powder charged therein are loaded into the accommodation space and are moved in a stepwise fashion toward the discharge part (from the first section to the fourth section), and gas is supplied five times every load or movement of the subchambers. Here, since the charging amount of powder is increased about twelvefold under the condition that the same amount of gas is supplied the same number of times (20 times), it is possible to efficiently perform surface treatment of powder.

### Experimental Example 2: STEM Image Analysis

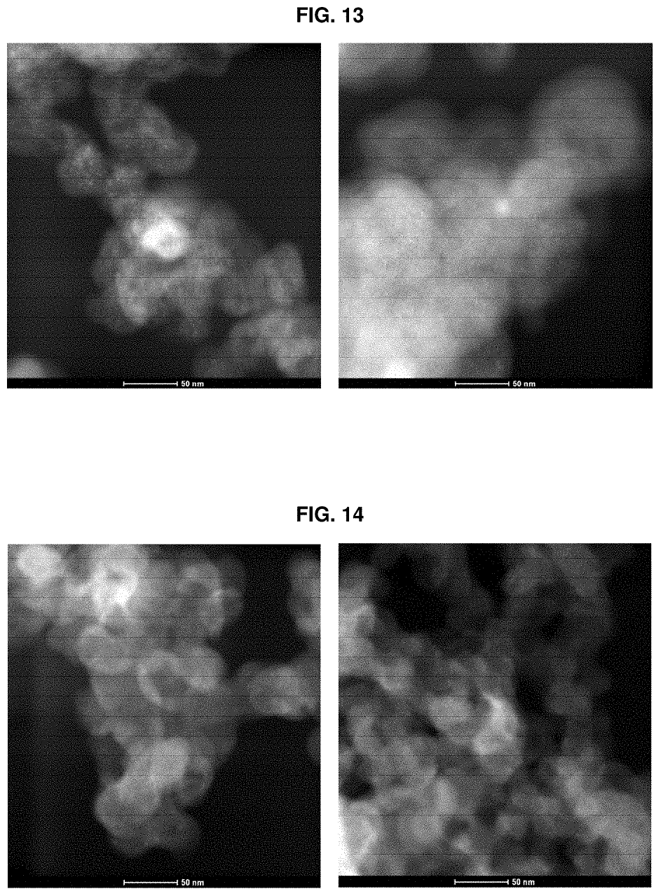

FIG. 12 shows images of scanning transmission electron microscopy (STEM) of powder (i.e., Pt-supported catalyst), which is surface-treated in the subchambers in the first and fourth sections in the Example in this order. FIG. 13 shows other STEM images of Pt-supported catalyst in the subchamber in the first section in the Example, and FIG. 14 shows other STEM images of PT-supported catalyst in the subchamber in the fourth section in the Example.

Referring to FIGS. 12 to 14, it will be appreciated that the uniformity of Pt coating of the Pt-supported catalyst disposed in the subchamber, particularly in the fourth section, is improved for the Pt-supported catalyst produced in the Example compared to that of the Comparative Example. Further, It will be appreciated that an amount of supported Pt in the subchamber in the fourth section is increased, compared to the subchamber in the first section, and that more of the supplied Pt precursor is consumed in a section closer to the supply part (injection part).

### Experimental Example 3: Electrochemical Activity Analysis

From Table 1, It will be appreciated that the charge amount of hydrogen desorption (QH, mC) of surface-treated powder (i.e., Pt-supported catalyst) is increased in the same process time (i.e., the same number of cycles). Further, it will be appreciated that an electrochemical surface area (ECSA) is greatly increased to 189.6 m2/g from 111.8 m2/g in the same process time (i.e., the same number of cycles). In the case of the Example (the subchamber in the fourth section), it will be appreciated that it is possible to realize excellent catalyst characteristics by virtue of the stepwise movement and ALD process. In other words, it will be appreciated that the Example and the Comparative Example show significant differences therebetween as to the amount and uniformity of Pt supported on carbon black powder even though the ALD process is repeatedly performed 20 cycles both in the Example and the Comparative Example. In particular, when a plurality of subchambers are loaded into the accommodation space and moved toward the discharge part in a stepwise fashion, and the ALD process is performed 5 cycles every movement of the subchambers, it is possible to uniformly coat powder with gas by virtue of prevention of overgrowth.

### Experimental Example 4: Energy-Dispersive X-Ray Spectroscopy (EDS) Analysis

Gas in the subchambers in first and fourth sections in the Example was subjected to EDS analysis in order to obtain composition of Pt. The atom weight ratio (wt %) and atom number ratio (at %) of Pt are represented in Table 2.

TABLE 2

| | | wt % | at % |
|---|---|---|---|
| Example | Subchamber in first section | 13.28 | 00.95 |
| | Subchamber in fourth section | 00.00 | 00.00 |

From the results of Table 2, it will be appreciated that, in contrast to the composition of Pt in the subchamber in the first section, almost no Pt is found in the subchamber in the fourth section. It will be appreciated that a larger amount of carbon black and Pt precursor are brought into contact with each other in a section at approximately (or close) to the supply part (injection part) than a section at approximately (or close to) the discharge part. Accordingly, through the deposition of PT in combination with the stepwise movement of the subchambers, it is maximize a use rate of expensive noble metal precursors such as Pt.

As is apparent from the above description, the surface treatment apparatus for surface-treating powder and the method of surface-treating powder using the apparatus according to some embodiments of the present disclosure are able to improve the effect of surface treatment of powder and to greatly increase the amount of production of surface-treated powder by controlling the size and number of subchambers.

Further, since a new subchamber, which is newly added to the chamber, is loaded at approximately (or close to) the injection part, and a subchamber, which has been already loaded, moves from away the injection part, it is possible to efficiently control contact between a large amount of powder and gas.

Accordingly, in the case of performing surface treatment by causing the metal precursor to contact the surface of the powder, it is possible to uniformly deposit the metal precursor and thus to realize a large electrochemical surface area and excellent catalyst characteristics, compared to a conventional method.

Consequently, since a specific surface area to mass of the metal precursor used in the surface treatment is increased, it is possible to reduce the required amount of metal while improving the performance of the catalyst. Consequently, it is possible to realize reduction of cost and mass production and thus to improve production efficiency.

The effects of the present disclosure are not limited to the above-mentioned effects. The effects of the present disclosure should be construed as including all effects that can be deduced from the above description.

The disclosure has been described in detail with reference to preferred embodiments thereof. However, it will be appreciated by those skilled in the art that changes may be made in these embodiments without departing from the principles and spirit of the disclosure, the scope of which is defined in the appended claims and their equivalents.

What is claimed is:

1. A surface treatment apparatus for surface-treating powder, comprising:
a chamber defining an accommodation space therein;
an injection part provided at a first end of the chamber so as to inject gas into the accommodation space;
a discharge part provided at a second end of the chamber that is opposite the first end so as to discharge unreacted gas from the accommodation space; and
at least one subchamber loaded in the accommodation space of the chamber between the first end and the second end,
wherein powder is charged in the subchamber,
wherein the subchamber includes a mesh structure provided in at least one surface of the subchamber so as to allow the gas to be introduced into the subchamber, and
wherein the subchamber is movable from the first end to the second end.

2. The surface treatment apparatus according to claim 1,
wherein the gas is injected into the accommodation space from the injection part at least once when the subchamber is moved toward the second end from the first end.

3. The surface treatment apparatus according to claim 1,
wherein the gas contacts the powder charged in the subchamber so as to perform atomic layer deposition (ALD).

4. The surface treatment apparatus according to claim 1, wherein:
the mesh structure includes a micro-hole, and
a size of the micro-hole is larger than a size of a particle included in the gas but smaller than the powder.

5. The surface treatment apparatus according to claim 4,
wherein the size of the micro-hole is in a range of 10 μm to 100 μm.

6. The surface treatment apparatus according to claim 1, further comprising:
a controller,
wherein the controller is configured to load the subchamber in the accommodation space toward the first end, and to remove the subchamber from the accommodation space after the subchamber has been moved toward the second end.

7. The surface treatment apparatus according to claim 1, further comprising:
a pumping part,
wherein the pumping part is configured to discharge the unreacted gas in the accommodation space to an outside of the accommodation space through the discharge part.

8. The surface treatment apparatus according to claim 1,
wherein when a first subchamber in the chamber is moved toward the second end, a second subchamber is added to the chamber at approximately the first end so as to be moved toward the second end.

9. The surface treatment apparatus according to claim 1,
wherein the accommodation space in the chamber between the first end and the second end is compartmented into N sections (N being a natural number equal to or greater than 2), and
wherein the subchamber is moved from a first section located at approximately the first end toward an Nth section at approximately the second end in a stepwise fashion.

10. The surface treatment apparatus according to claim 9,
wherein when a first subchamber is moved from a first section toward an Nth section, a second subchamber is added to the first section so as to be moved toward the Nth section.

11. The surface treatment apparatus according to claim 9, wherein
when the subchamber is moved to a next section and is positioned thereat, gas is injected into the accommodation space from the injection part.

12. The surface treatment apparatus according to claim 9, further comprising a controller,
wherein the controller is configured to load the subchamber into the first section in the accommodation space, and to remove the subchamber from the accommodation space when the subchamber is positioned at the Nth section.

13. The surface treatment apparatus according to claim 1,
wherein the powder includes carbon (C), and the gas includes a metal precursor.

14. A method of surface-treating powder using the surface treatment apparatus, comprising:
providing a surface treatment apparatus including a chamber defining an accommodation space therein, an injection part provided at a first end of the chamber so as to inject gas into the accommodation space, and a discharge part provided at a second end of the chamber that is opposite the first end so as to discharge unreacted gas from the accommodation space;
loading a first subchamber in the accommodation space so as to be closer to the first end than to the second end;
moving the first subchamber toward the second end; and
loading a second subchamber into the accommodation space between the first subchamber and the first end,
wherein when the first subchamber is moved, gas is injected into the accommodation space from the injection part at least once.

15. The method according to claim 14,
wherein the accommodation space between the first end and the second end is compartmented into N sections (N being a natural number equal to or greater than 2),
wherein loading the first subchamber into the accommodation space includes loading the first subchamber into a first section at approximately the first end,
wherein moving the first subchamber toward the second end includes moving the first subchamber from the first section to an Nth section at approximately the second end in a stepwise fashion, and
wherein loading the second subchamber into the accommodation space includes additionally loading the second subchamber into the first section when the first subchamber is moved toward the Nth section.

16. The method according to claim 15,
wherein as the first subchamber is moved from the first section toward the Nth section in a stepwise fashion, the second subchamber, which has been added to the first section, is also moved toward the Nth section.

17. The method according to claim 15,
wherein when the subchamber is moved from a section to another adjacent section and is positioned thereat, gas is injected into the accommodation space from the injection part at least once.

18. The method according to claim 15,
wherein when the subchamber is positioned at the Nth section in the accommodation space, the subchamber is removed under a control of a controller.

19. The method according to claim 14,
wherein injecting the gas includes:
a first operation of supplying the gas including a metal precursor;
a second operation of performing purging with inert gas;
a third operation of supplying reaction gas for converting the metal precursor into metal; and
a fourth operation of performing purging with inert gas.

20. The method according to claim 19,
wherein the first to fourth operations are set to be one cycle, and the operations are performed for at least one cycle.
